(19) United States
(12) Patent Application Publication
(10) Pub. No.: US 2026/0324334 A1
(43) Pub. Date: Oct. 15, 2026

(54) PROTECTIVE FILM AGENT AND METHOD OF PROCESSING WORKPIECE

(71) Applicant: DISCO CORPORATION, Tokyo (JP)

(72) Inventors: Yuki NISHIJIMA, Tokyo (JP); Sho OSAWA, Tokyo (JP); Yukinobu OHURA, Tokyo (JP)

(21) Appl. No.: 19/640,607

(22) Filed: Apr. 7, 2026

(30) Foreign Application Priority Data
Apr. 11, 2025 (JP) 2025-065621
Apr. 11, 2025 (JP) 2025-065622

(51) Int. Cl. H10P 58/00; H10P 14/68; H10P 54/20

(52) U.S. Cl. CPC H10P 58/20; H10P 14/683; H10P 54/20

(57) ABSTRACT

There is provided a protective film agent from which to form a protective film on a workpiece, the protective film agent including a water-soluble resin whose polydispersity is 4.0 or more. There is also provided a protective film agent from which to form a protective film on a workpiece, the protective film agent including a water-soluble resin and an organic solvent, the organic solvent having a boiling point of 140° C. or higher and having a content percentage of 3 wt % or higher.

### BACKGROUND OF THE INVENTION

### Field of the Invention

The present invention relates to a protective film agent from which to form a protective film on a workpiece, a method of processing a workpiece along streets established thereon, and a method of manufacturing chips from a workpiece by dividing the workpiece along streets established thereon.

### Description of the Related Art

According to device chip manufacturing processes, device chips are produced from a wafer that has devices constructed in respective areas demarcated thereon by a grid of streets or projected dicing lines. The wafer is divided along the streets into chips incorporating the respective devices, also called “device chips.” The device chips thus fabricated will be assembled into various electronic units such as cellular phones and personal computers.

The wafer is often divided by a cutting apparatus having an annular cutting blade that cuts into the wafer while in rotation. Recent years have also found a laser beam for use in dividing a wafer. For example, the laser beam is applied to the wafer along streets established thereon to cut the wafer into chips by way of laser processing. A wafer to be processed by a laser beam may be coated with a protective film in order to prevent swarf such as debris from being deposited on the wafer at the time at which the laser beam is applied to the wafer (see, for example, Japanese Patent Laid-open No. 2006-140311).

Moreover, there has been proposed a process referred to as “plasma dicing” for dividing a wafer by way of plasma etching. According to the plasma dicing, first, a wafer to be divided is coated with a protective film, and then, the protective film is patterned to expose streets on the wafer. Thereafter, a plasmatized etching gas is supplied to the wafer through the protective film used as a mask, performing plasma etching on the wafer along the streets to thereby divide the wafer into a plurality of chips (see, for example, Japanese Patent Laid-open No. 2016-207737).

### SUMMARY OF THE INVENTION

As described above, when a workpiece such as a wafer is to be processed by way of laser processing or plasma etching, it is customary to coat the workpiece with a protective film. The protective film is formed by, for example, supplying an entire surface of the workpiece with a protective film agent as a protective film material by way of spin coating or spray coating, and then drying the protective film agent into a solid protective film on the surface of the workpiece.

However, when the protective film agent applied to coat the workpiece is dried, shrinkage of the protective film may occasionally produce a crack. If the workpiece with the cracked protective film is thereafter processed, then the workpiece may suffer processing failures due to the cracked protective film failing to give sufficient protection to the workpiece. For example, a crack of the protective film makes a part of the workpiece expose when a workpiece is to be processed by way of laser processing, and this results in failure of prevention of swarf being deposited on the workpiece in some cases. Providing the workpiece is processed by way of plasma etching, the etching gas may be introduced into the cracks in the protective film, possibly performing plasma etching on unwanted regions of the workpiece.

It is therefore an object of the present invention to provide a protective film agent from which to form a protective film on a workpiece, a method of processing a workpiece, and a method of manufacturing chips from a workpiece, while preventing the workpiece from suffering processing failures.

In accordance with an aspect of the present invention, there is provided a protective film agent from which to form a protective film on a workpiece, the protective film agent including a water-soluble resin whose polydispersity is 4.0 or more.

The water-soluble resin may have a number average molecular weight in a range from 10,000 to 50,000 and a weight average molecular weight in a range from 200,000 to 1,500,000. The protective film agent may further include a light absorber. The protective film agent may further include water as a solvent. The protective film agent may further include an organic solvent as the solvent.

In accordance with another aspect of the present invention, there is provided a method of processing a workpiece along streets established thereon, the method including supplying the workpiece with a protective film agent that includes a water-soluble resin whose polydispersity is 4.0 or more to form a protective film on the workpiece, applying a laser beam that is absorbable by the protective film to a portion of the protective film along the streets to remove the portion of the protective film along the streets, and supplying the workpiece with a plasmatized etching gas through the protective film to perform plasma etching on the workpiece along the streets.

In accordance with a further aspect of the present invention, there is provided a method of processing a workpiece along streets established thereon, the method including supplying the workpiece with a protective film agent that includes a water-soluble resin whose polydispersity is 4.0 or more to form a protective film on the workpiece, and applying a laser beam that is absorbable by the workpiece through the protective film to the workpiece along the streets to form laser-processed grooves along the streets in the workpiece.

In accordance with a still further aspect of the present invention, there is provided a method of manufacturing chips by dividing a workpiece along streets established thereon, the method including supplying the workpiece with a protective film agent that includes a water-soluble resin whose polydispersity is 4.0 or more to form a protective film on the workpiece, applying a laser beam that is absorbable by the protective film to a portion of the protective film along the streets to remove the portion of the protective film along the streets, and supplying the workpiece with a plasmatized etching gas through the protective film to perform plasma etching on the workpiece along the streets, thereby dividing the workpiece along the streets into the chips.

In accordance with a still further aspect of the present invention, there is provided a method of manufacturing chips by dividing a workpiece along streets established thereon, the method including supplying the workpiece with a protective film agent that includes a water-soluble resin whose polydispersity is 4.0 or more to form a protective film on the workpiece, and applying a laser beam that is absorbable by the workpiece through the protective film to the workpiece along the streets to form laser-processed grooves along the streets in the workpiece, thereby dividing the workpiece along the streets into the chips.

In accordance with a still further aspect of the present invention, there is provided a protective film agent from which to form a protective film on a workpiece, the protective film agent including a water-soluble resin and an organic solvent, the organic solvent having a boiling point of 140° C. or higher and having a content percentage of 3 wt % or higher.

The protective film agent may further include a light absorber. The protective film agent may further include water. The organic solvent may be a water-soluble organic solvent.

In accordance with a still further aspect of the present invention, there is provided a method of processing a workpiece along streets established thereon, the method including supplying the workpiece with a protective film agent including a water-soluble resin and an organic solvent, the organic solvent having a boiling point of 140° C. or higher and having a content percentage of 3 wt % or higher, to form a protective film on the workpiece, applying a laser beam that is absorbable by the protective film to a portion of the protective film along the streets to remove the portion of the protective film along the streets, and supplying the workpiece with a plasmatized etching gas through the protective film to perform plasma etching on the workpiece along the streets.

In accordance with a still further aspect of the present invention, there is provided a method of processing a workpiece along streets established thereon, the method including supplying the workpiece with a protective film agent including a water-soluble resin and an organic solvent, the organic solvent having a boiling point of 140° C. or higher and having a content percentage of 3 wt % or higher, to form a protective film on the workpiece, and applying a laser beam that is absorbable by the workpiece through the protective film to the workpiece along the streets to form laser-processed grooves along the streets in the workpiece.

In accordance with a still further aspect of the present invention, there is provided a method of manufacturing chips by dividing a workpiece along streets established thereon, the method including supplying the workpiece with a protective film agent including a water-soluble resin and an organic solvent, the organic solvent having a boiling point of 140° C. or higher and having a content percentage of 3 wt % or higher, to form a protective film on the workpiece, applying a laser beam that is absorbable by the protective film to a portion of the protective film along the streets to remove the portion of the protective film along the streets, and supplying the workpiece with a plasmatized etching gas through the protective film to perform plasma etching on the workpiece along the streets, thereby dividing the workpiece along the streets into the chips.

In accordance with a still further aspect of the present invention, there is provided a method of manufacturing chips by dividing a workpiece along streets established thereon, the method including supplying the workpiece with a protective film agent including a water-soluble resin and an organic solvent, the organic solvent having a boiling point of 140° C. or higher and having a content percentage of 3 wt % or higher, to form a protective film on the workpiece, and applying a laser beam that is absorbable by the workpiece through the protective film to the workpiece along the streets to form laser-processed grooves along the streets in the workpiece, thereby dividing the workpiece along the streets into the chips.

The protective film may be formed on the workpiece by way of spin coating or spray coating.

The protective film agent according to the aspect of the present invention includes a water-soluble resin whose polydispersity is 4.0 or more. The protective film agent that is used to form a protective film on a workpiece makes the protective film less likely to develop cracks therein. When the workpiece is subsequently processed, therefore, the workpiece is properly protected against damage by the protective film and prevented from suffering processing failures.

The protective film agent according to the other aspect of the present invention includes an organic solvent whose boiling point is 140° C. or higher and whose content percentage is 3 wt % or higher. The protective film agent used to form a protective film on a workpiece relieves abrupt shrinkage of the protective film at the time at which the protective film agent is dried, and makes the protective film less likely to crack. Consequently, when the workpiece is subsequently processed, the workpiece is properly protected against damage by the protective film and prevented from suffering processing failures.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a perspective view illustrating a workpiece;

FIG. 2 is a flowchart of a method of processing a workpiece;

FIG. 3 is a front elevational view, partly in cross section, illustrating a workpiece in a protective film forming step of the method;

FIG. 4A is an enlarged fragmentary front elevational view, partly in cross section, illustrating the workpiece in a protective film removing step of the method;

FIG. 4B is an enlarged fragmentary front elevational view, partly in cross section, illustrating the workpiece in a plasma etching step of the method;

FIG. 5 is a flowchart of a method of processing a workpiece according to a modification; and

FIG. 6 is a front elevational view, partly in cross section, illustrating a workpiece in a laser beam applying step of the method according to the modification.

### DETAILED DESCRIPTION OF THE PREFERRED EMBODIMENTS

### First Embodiment

A first embodiment of the present invention will be described in detail below with reference to the accompanying drawings. First, a structural example of a workpiece on which to form a protective film from a protective film agent according to the first embodiment will be described below.

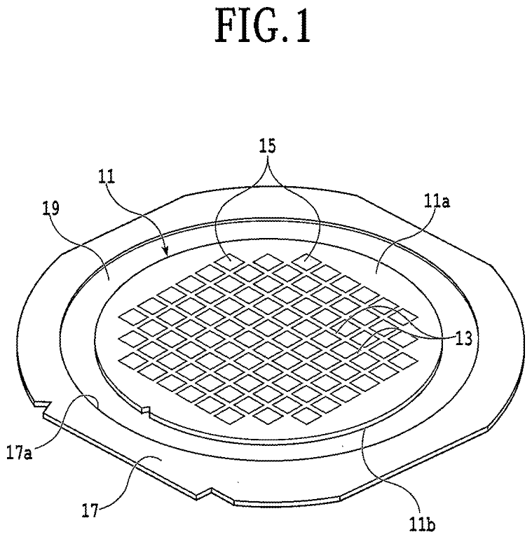

FIG. 1 illustrates a workpiece 11 in perspective. After the workpiece 11 has been coated with a protective film, the workpiece 11 is processed by way of plasma etching or laser processing, for example, as described later. Therefore, the workpiece 11 represents an object to be coated with a protective film.

As illustrated in FIG. 1, the workpiece 11 is typically in the form of a disk-shaped wafer made of a semiconductor material such as monocrystalline silicon. The workpiece 11 has a face side, i.e., a first surface, 11a and a reverse side, i.e., a second surface, 11b that lie generally parallel to each other. The face side 11a has a plurality of rectangular areas demarcated by a grid of streets or projected dicing lines 13 established on the workpiece 11. Devices 15 such as integrated circuits (ICs), large-scale-integration (LSI) circuits, light-emitting diodes (LEDs), or micro-electro-mechanical systems (MEMS) devices, for example, are constructed respectively in the areas demarcated by the streets 13. The workpiece 11 will be divided along the streets 13 into a plurality of chips, i.e., device chips, including the respective devices 15.

Though the workpiece 11 is herein illustrated as a wafer by way of example, the workpiece 11 is not limited to any particular materials, shapes, structures, and sizes, for example. The workpiece 11 may be a wafer or substrate made of any of semiconductor materials other than silicon, e.g., gallium arsenide (GaAs), silicon carbide (Sic), indium phosphide (InP), or gallium nitride (GaN), or any of other materials including sapphire, glass, ceramic, resin, and metal, for example. The devices 15 are not limited to any particular kinds, quantities, shapes, structures, sizes, and layouts, for example.

While the workpiece 11 is being coated with a protective film or processed, the workpiece 11 may be supported by an annular frame 17 for better handling, e. g., safe transport and secure positioning for protection against damage. The annular frame 17 is made of metal such as stainless steel (SUS) and has a circular opening 17a defined centrally therethrough thicknesswise. The opening 17a is larger in diameter than the workpiece 11 supported by the frame 17.

A circular sheet 19 is affixed to the workpiece 11 and the frame 17. The sheet 19 is in the form of a tape including a circular film base and an adhesive layer, e.g., a glue layer, applied to an upper surface, as depicted, of the circular film base. The circular film base is made of resin such as polyolefin, polyvinyl chloride, or polyethylene terephthalate, whereas the adhesive layer is made of an adhesive or the like of epoxy, acryl, or rubber, for example. The sheet 19 may alternatively be a thermocompression bonding sheet that is free of an adhesive layer and can be bonded to the workpiece 11 and the frame 17 by way of thermal pressure bonding.

The workpiece 11, the frame 17, and the sheet 19 are put together as follows: The workpiece 11 is put within the opening 17a of the frame 17. Then, the sheet 19 is placed beneath the workpiece 11 and the frame 17, and has its central area affixed to the reverse side 11b of the workpiece 11 and has its outer circumferential area affixed to the frame 17. The workpiece 11 is now supported on the frame 17 by the sheet 19.

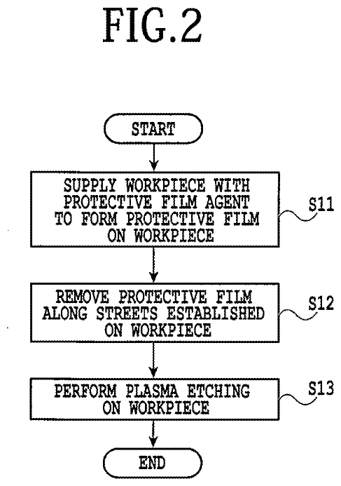

A method of processing a workpiece, i.e., the workpiece 11, according to the present embodiment will be described below. FIG. 2 is a flowchart of the method of processing the workpiece 11. According to the present embodiment, the workpiece 11 is supplied with a protective film agent to coat itself with a protective film in protective film forming step S11. Thereafter, the protective film formed on the workpiece 11 is partly removed along the streets 13 in protective film removing step S12. Then, plasma etching is performed on the workpiece 11 through the protective film that remains on the workpiece 11 as a mask, in plasma etching step S13.

According to the present embodiment, the protective film agent referred to above is used to form the protective film on the workpiece 11 in protective film forming step S11. Protective film forming step S11 represents a method of forming a protective film according to the present embodiment. According to the present embodiment, a method of dividing the workpiece 11 along the streets 13 into a plurality of chips will be described below as an example of the method of processing the workpiece. Protective film forming step S11, protective film removing step S12, and plasma etching step S13 illustrated in FIG. 2 altogether represent a method of manufacturing chips according to the present embodiment.

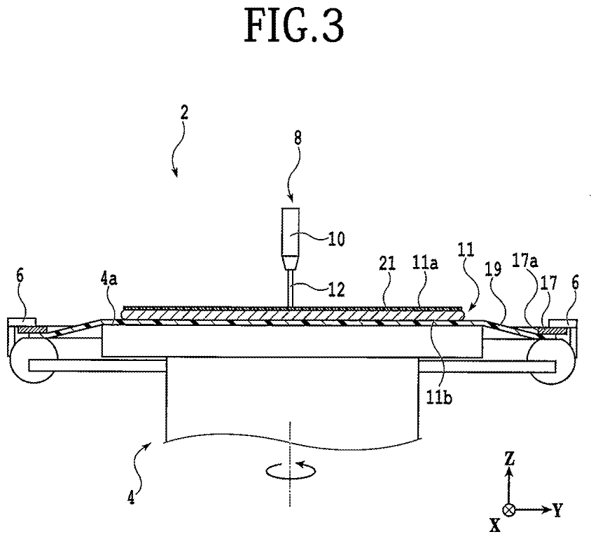

FIG. 3 illustrates in front elevation, partly in cross section, the workpiece 11 in protective film forming step S11. The protective film is formed on the workpiece 11 by a protective film forming apparatus, i.e., a protective film forming unit, 2, for example. In FIG. 3 and some other figures, an X-axis or first horizontal axis and a Y-axis or second horizontal axis extend perpendicularly to each other. A Z-axis or upward/downward, heightwise, or vertical axis extends perpendicularly to the X-axis and the Y-axis. According to the present embodiment, the face side 11a of the workpiece 11 will be described as a surface to be coated with the protective film.

The protective film forming apparatus 2 includes a holding table or chuck table 4 for holding the workpiece 11 thereon. The holding table 4 has a flat upper surface lying generally parallel to a horizontal plane or XY plane that extends along the X-axis and the Y-axis. The upper surface of the holding table 4 acts as a holding surface 4a for holding the workpiece 11 thereon. The holding surface 4a that is porous in nature is fluidly connected to a suction source, not depicted, such as an ejector through a fluid channel, not depicted, defined in the holding table 4 and a valve, not depicted.

The holding table 4 is a spinner table that is rotatable while holding the workpiece 11 on the holding surface 4a. Specifically, the holding table 4 is coupled to a rotary actuator, not depicted, such as an electric motor that rotates the holding table 4 about its central axis that extends generally parallel to the Z-axis. A plurality of clamps 6 are provided at regular angular intervals around the holding table 4 for gripping the frame 17 that supports the workpiece 11 and securing the frame 17 in position.

The protective film forming apparatus 2 also includes a protective film agent supply unit 8 for supplying a protective film agent 12 as a protective film material to the workpiece 11 held on the holding table 4. The protective film agent supply unit 8 includes a protective film agent supply nozzle 10 for supplying the protective film agent 12 that is a liquid material containing a water-soluble resin to the workpiece 11 held on the holding table 4. The protective film agent supply nozzle 10 is disposed above the holding table 4. When the protective film agent supply unit 8 is in operation, the protective film agent supply nozzle 10 supplies the protective film agent 12 through its lower outlet port to the workpiece 11 held on the holding table 4.

The protective film agent 12 is produced by dissolving a solute into a solvent. For example, the protective film agent 12 contains water and an organic solvent as the solvent and also contains a water-soluble resin and a light absorber as the solute. Providing the solvent contains water and an organic solvent, the organic solvent should preferably be water-soluble. The water-soluble organic solvent is such an organic solvent that 0.5 g or more thereof can be dissolved in 100 g of water at 25° C., for example. The water-soluble resin is such a resin that 0.5 g or more thereof can be dissolved in 100 g of water at 25° C., for example.

The organic solvent has a function to dissolve an additive such as a light absorber and a function to reduce the surface tension of the protective film agent 12 supplied to the workpiece 11. The organic solvent should preferably be methyl alcohol, ethyl alcohol, isopropyl alcohol, ester, alkylene glycol monoalkyl ether, alkylene glycol, or alkylene glycol monoalkyl ether acetate, for example. Particularly, propylene glycol monomethyl ether (PGME) should preferably be used as alkylene glycol monoalkyl ether. Specific examples of the organic solvent will be described in greater detail later with respect to Examples.

The water-soluble resin should preferably be polyvinyl pyrrolidone (PVP), polyvinyl alcohol (PVA), hydroxypropyl cellulose, polyethylene glycol, polyethylene oxide, methyl cellulose, ethyl cellulose, polyacrylic acid, poly-N-vinyl acetamide, polystyrene sulfonic acid, special nylons, phenolic resins, methylol melamine resins, or polyglycerin, for example. Graft polymer of any of the above resins may be used as the water-soluble resin.

The light absorber is an additive having a property to absorb a laser beam that is applied to the workpiece 11 or the protective film formed on the workpiece 11. The light absorber should preferably be a cinnamic acid-based compound such as ferulic acid or caffeic acid, a benzophenone-based compound such as hydroxybenzophenone or 2-hydroxy-4-methoxy-benzophenone-5-sulfonic acid, an anthraquinone-based compound such as carminic acid, or a flavonoid-based compound such as α-glucosylrutin, for example.

A protective film is formed on the workpiece 11 by a spin coating process using the protective film forming apparatus 2. For forming a protective film on the workpiece 11, the workpiece 11 is held on the holding table 4. Specifically, the workpiece 11 is placed on the holding surface 4a of the holding table 4 such that the face side 11a, i.e., the surface to be coated, is exposed upwardly and the reverse side 11b, i.e., the sheet 19 side, faces the holding surface 4a. The frame 17 is secured in position by the clamps 6. Then, the suction source is actuated to apply a suction force, i.e., a negative pressure, to the holding surface 4a, causing the holding table 4 to hold the workpiece 11 under suction on the holding surface 4a with the sheet 19 interposed therebetween.

Now, the protective film agent 12 is supplied to the workpiece 11 to form a protective film 21 on the workpiece 11, i.e., to coat the workpiece 11 with the protective film 21. Specifically, the positional relation between the holding table 4 and the protective film agent supply nozzle 10 is adjusted to align the protective film agent supply nozzle 10 with the central axis of the holding table 4, i.e., the center of the holding surface 4a. For example, a swing arm, not depicted, for turning the protective film agent supply nozzle 10 along the XY plane is coupled to the protective film agent supply nozzle 10. The swing arm is actuated to turn the protective film agent supply nozzle 10 until the protective film agent supply nozzle 10 is positioned directly above the central axis of the holding table 4.

Then, while the holding table 4 is being rotated about its central axis, the protective film agent supply nozzle 10 supplies the protective film agent 12 that is a liquid material containing a water-soluble resin to the face side 11a of the workpiece 11 held on the holding table 4. The supplied protective film agent 12 is first applied to a central area of the workpiece 11 and then spread radially outwardly from the central area of the workpiece 11 toward its outer circumferential edge under centrifugal forces generated by the rotation of the holding table 4, coating the entire face side 11a of the workpiece 11 with the protective film agent 12. When the workpiece 11 has been supplied with a predetermined amount of the protective film agent 12, the protective film agent supply nozzle 10 stops supplying the protective film agent 12 to the workpiece 11.

Even after the protective film agent 12 has stopped being supplied to the workpiece 11, the holding table 4 is continuously rotated for a certain period of time. Thus, the protective film agent 12 on the face side 11a of the workpiece 11 is now dried and solidified into a solid protective film 21, which contains a water-soluble resin, having a predetermined thickness on the face side 11a of the workpiece 11. At this time, a gas such as air may be applied to the protective film agent 12 on the face side 11a of the workpiece 11, accelerating the drying process on the protective film agent 12.

The protective film 21 may be formed on the workpiece 11 by a process other than the spin coating process. For example, the protective film 21 may be formed on the workpiece 11 by a spray coating process. The spray coating process may be performed by a protective film agent supply nozzle for atomizing the protective film agent 12 and supplying the atomized protective film agent 12 to the workpiece 11, instead of the protective film agent supply nozzle 10 described above. When the atomized protective film agent 12 is supplied from the protective film agent supply nozzle to the face side 11a of the workpiece 11, the face side 11a of the workpiece 11 is coated in its entirety with the protective film agent 12.

When the protective film agent 12 that has coated the workpiece 11 is dried and solidified into the protective film 21, the protective film 21 possibly tends to shrink abruptly and crack under stresses developed upon shrinkage. If the workpiece 11 with the cracked protective film 21 formed thereon is processed, then the workpiece 11 is not fully protected by the protective film 21 and may possibly suffer processing failures.

According to an aspect of the present embodiment, the protective film 21 is prevented from cracking by making the protective film agent 12 contain a water-soluble resin whose polydispersity is 4.0 or more. The polydispersity is represented by the ratio Mw/Mn of the weight average molecular weight Mw to the number average molecular weight Mn of a polymer. According to the present embodiment, the polydispersity indicates the breadth of the molecular weight distribution of the water-soluble resin. If the polydispersity of the water-soluble resin contained in the protective film agent 12 is large, the high-molecular-weight component imparts tenacity to the protective film 21, and the low-molecular-weight component imparts flexibility to the protective film 21. This makes the protective film 21 pliable and durable when it changes in shape upon shrinkage as the protective film agent 12 is dried into the protective film 21. By setting the polydispersity of the water-soluble resin to 4.0 or more, the protective film 21 obtained after thoroughly drying the protective film agent 12 is less liable to crack and hence is prevented from cracking.

A water-soluble resin whose polydispersity is of a predetermined value or higher may be produced by mixing a plurality of resins whose polydispersities are smaller than the predetermined value. For example, a material having a large average molecular weight and a material having a small average molecular weight may be mixed with each other to obtain a water-soluble resin whose polydispersity is larger than that of those materials. Moreover, the ratio at which a material having a large average molecular weight and a material having a small average molecular weight are mixed with each other may be adjusted to obtain a water-soluble resin having a desired polydispersity. By thus using a process of mixing two or more kinds of resin having different average molecular weights, it is easy to produce a water-soluble resin whose polydispersity is 4.0 or more.

For producing a water-soluble resin by mixing two or more kinds of resin with each other, a plurality of different high-polymer materials may be mixed with each other, or polymers of the same material that have different average molecular weights may be mixed with each other. In the latter case, two or more kinds of polymer having different K values, i.e., viscosity characteristic values, that represent property values proportional to average molecular weights may be used.

The polydispersity of the water-soluble resin contained in the protective film agent 12 is appropriately set to a value in the range from 4.0 to more. In particular, in order to effectively prevent the protective film 21 from cracking, the polydispersity of the water-soluble resin should preferably be 4.2 or more, or more preferably be 11.1 or more. The number average molecular weight and weight average molecular weight of the water-soluble resin contained in the protective film agent 12 are appropriately set to values in the range that makes it possible to achieve the polydispersity of 4.0 or more. For example, the number average molecular weight of the water-soluble resin is in the range from 10,000 to 50,000, whereas the weight average molecular weight of the water-soluble resin is in the range from 200,000 to 1,500,000.

According to another aspect of the present embodiment, the protective film agent 12 contains an organic solvent whose boiling point is 140° C. or higher and whose content percentage is adjusted to 3 wt % or higher. The organic solvent thus contained makes the protective film agent 12 volatile gradually, relieving abrupt shrinkage and stress of the protective film 21. As a result, the protective film 21 is prevented from cracking.

If the boiling point of the organic solvent is higher than 140° C., then the protective film 21 is more effectively prevented from abrupt shrinkage. On the other hand, if the boiling point of the organic solvent is equal to or lower than a certain point, then the period of time required to dry the protective film agent 12 is shortened, resulting in higher productivity. Consequently, the boiling point of the organic solvent may preferably be in the range from 150° C. to 300° C., or more preferably be in the range from 170° C. to 300° C., or much more preferably be in the range from 170° C. to 250° C. Furthermore, in order to further relieve abrupt shrinkage of the protective film 21, the boiling point of the organic solvent may be 190° C. or higher.

The content percentage of the organic solvent represents the ratio of the mass of the organic solvent to the overall mass of the protective film agent 12. If the protective film agent 12 contains 3 wt % or more of the high-boiling-point organic solvent described above, then it is possible to more effectively prevent abrupt shrinkage of the protective film 21. On the other hand, if the content percentage of the high-boiling-point organic solvent is equal to or lower than a certain level, then the period of time required to dry the protective film agent 12 is shortened, resulting in higher productivity. Consequently, the content percentage of the organic solvent may preferably be in the range from 3 to 70 wt % or more preferably be in the range from 10 to 50 wt %.

Next, the workpiece 11 coated with the protective film 21 is processed and divided into a plurality of chips in a processing step. In the processing step, for example, the protective film 21 formed on the workpiece 11 is partly removed along the streets 13 in protective film removing step S12. Then, plasma etching is performed on the workpiece 11 through the protective film that remains on the workpiece 11 as a mask, in plasma etching step S13.

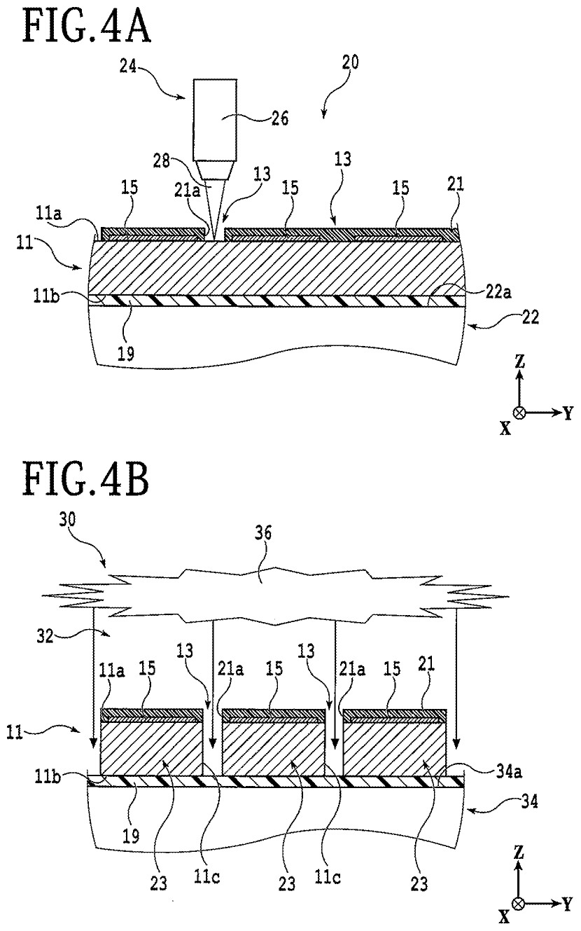

FIG. 4A illustrates in enlarged fragmentary front elevation, partly in cross section, the workpiece 11 in protective film forming step S12. In protective film forming step S12, the protective film 21 formed on the workpiece 11 is partly removed along the streets 13, so that the protective film 21 is patterned. The protective film 21 is partly removed by way of laser processing using a laser processing apparatus 20, for example.

The laser processing apparatus 20 includes a holding table or chuck table 22 for holding the workpiece 11 thereon. The holding table 22 has a flat upper surface lying generally parallel to the horizontal plane or XY plane. The upper surface of the holding table 22 acts as a holding surface 22a for holding the workpiece 11 thereon. The holding surface 22a that is porous in nature is fluidly connected to a suction source, not depicted, such as an ejector through a fluid channel, not depicted, defined in the holding table 22 and a valve, not depicted.

The holding table 22 is coupled to a moving unit, not depicted, and a rotary actuator, not depicted. The moving unit includes a ball-screw-type moving mechanism, for example, and moves the holding table 22 in horizontal directions along the X-axis and the Y-axis. The rotary actuator includes an electric motor, for example, and rotates the holding table 22 about its central axis generally parallel to the Z-axis.

The laser processing apparatus 20 includes a laser beam applying unit 24 for applying a laser beam. The laser beam applying unit 24 includes a laser oscillator, not depicted, such as an yttrium aluminum garnet (YAG) laser, an yttrium vanadate (YVO₄) laser, or an yttrium lithium fluoride (YLF) laser, and a laser processing head 26 disposed above the holding table 22. The laser processing head 26 houses therein an optical system for guiding a pulse-oscillated laser beam 28 emitted from the laser oscillator toward the protective film 21 formed on the workpiece 11. The optical system has optical elements including among others a condensing lens for focusing the laser beam 28 at a predetermined position. The laser beam 28 applied from the laser processing head 26 to the protective film 21 processes the protective film 21.

In preparation for the laser processing of the protective film 21, the workpiece 11 is placed and held on the holding table 22. Specifically, the workpiece 11 is placed on the holding surface 22a of the holding table 22 such that the face side 11a, i.e., the protective film 21 side, is exposed upwardly and the reverse side 11b, i.e., the sheet 19 side, faces the holding surface 22a. Then, the suction source is actuated to apply a suction force, i.e., a negative pressure, to the holding surface 22a, causing the holding table 22 to hold the workpiece 11 under suction on the holding surface 22a with the sheet 19 interposed therebetween.

The holding table 22 is rotated about its central axis to orient the longitudinal direction of one of the streets 13 to be parallel to the X-axis that represents a processing-feed direction. Moreover, the holding table 22 is moved to adjust its position along the Y-axis that represents an indexing-feed direction until a region to be irradiated with the laser beam 28 is positioned on an extension of the street 13. Furthermore, the position of the laser processing head 26 and the layout of the optical system are adjusted to position the focused spot of the laser beam 28 at the same height as the protective film 21.

Now, while the laser processing head 26 is emitting the laser beam 28, the holding table 22 is moved along the X-axis with respect to the laser processing head 26. Accordingly, the holding table 22 and the laser beam 28 are moved relative to each other along the X-axis at a predetermined speed, i.e., a predetermined processing-feed rate, during which time the laser beam 28 is applied to the protective film 21. As a result, the protective film 21 is processed along the street 13 by the laser beam 28.

Conditions in which the laser beam 28 is applied to the protective film 21 are established to process the protective film 21 by way of laser ablation. Specifically, the laser beam 28 has a wavelength selected to cause at least part thereof to be absorbed by the protective film 21. In other words, the laser beam 28 is a laser beam absorbable by the protective film 21. Other conditions in which the laser beam 28 is applied to the protective film 21 are also established to ablate the protective film 21 appropriately.

When the laser beam 28 is applied to the protective film 21 along the street 13, an elongate linear portion of the protective film 21 along the street 13 is removed by way of laser ablation. The protective film 21 is thus partly removed along the street 13. As a result, a linear groove 21a is formed in the protective film 21 along the street 13. The linear groove 21a extends along the Z-axis from an upper surface of the protective film 21 to a lower surface thereof.

The light absorber contained in the protective film 21 absorbs the laser beam 28 thus applied to the protective film 21. Therefore, the ablation of the protective film 21 is accelerated, making it easy for the protective film 21 to be removed along the street 13.

Thereafter, the processing of the protective film 21 described above is repeated along the other streets 13. When linear grooves 21a are formed in the protective film 21 along all the streets 13, the protective film 21 has been patterned such that linear portions of the face side 11a of the workpiece 11 that overlap the streets 13 are exposed and the remaining other portions of the face side 11a of the workpiece 11 are covered with the protective film 21.

FIG. 4B illustrates in enlarged fragmentary front elevation, partly in cross section, the workpiece 11 in plasma etching step S13. After the protective film 21 has been patterned in protective film removing step S12, plasma etching is performed on the workpiece 11 through the patterned protective film 21 as a mask in plasma etching step S13. Plasma etching performed on the workpiece 11 in plasma etching step S13 to divide the workpiece 11 along the streets 13 is also referred to as plasma dicing.

In plasma etching step S13, a plasmatized etching gas is supplied to the face side 11a of the workpiece 11 through the patterned protective film 21, thereby performing plasma etching on the workpiece 11. For example, plasma etching is performed on the workpiece 11 by a plasma processing apparatus 30 that plasmatizes an etching gas and supplies the plasmatized etching gas to the workpiece 11.

The plasma processing apparatus 30 includes a processing chamber 32 in which plasma etching is performed. The processing chamber 32 houses a holding table or chuck table 34 for holding the workpiece 11 thereon. The holding table 34 has a flat upper surface lying generally parallel to the horizontal plane or XY plane. The upper surface of the holding table 34 acts as a holding surface 34a for holding the workpiece 11 thereon.

The holding table 34 is an electrostatic chuck table, for example, for holding the workpiece 11 thereon under electric forces, i.e., electrostatic attractive forces. Specifically, the holding table 34 has a plurality of electrodes, not depicted, embedded therein. When a predetermined voltage is applied to the electrodes, they produce coulomb forces acting between the holding table 34 and the workpiece 11, attracting the workpiece 11 to the holding surface 34a of the holding table 34.

In preparation for the plasma etching of the workpiece 11, first, the workpiece 11 is carried in the processing chamber 32 and is then placed and held on the holding table 34. Specifically, the workpiece 11 is placed on the holding surface 34a of the holding table 34 such that the face side 11a, i.e., the protective film 21 side, faces upwardly and the reverse side 11b, i.e., the sheet 19 side, faces the holding surface 34a.

Then, the processing chamber 32 is evacuated to a pressure ranging from 50 to 300 Pa, for example, and a plasmatized etching gas 36 is supplied to the workpiece 11 through the patterned protective film 21. Specifically, an etching gas introduced into the processing chamber 32 is plasmatized by an applied high-frequency voltage in the processing chamber 32 and then supplied as the plasmatized etching gas 36 to the face side 11a of the workpiece 11 held on the holding table 34. However, an etching gas that has been plasmatized outside of the processing chamber 32 may be introduced into the processing chamber 32 and supplied as the plasmatized etching gas 36 to the workpiece 11.

If the workpiece 11 is a monocrystalline silicon wafer, then an etching gas including a fluorine gas such as tetrafluoromethane (CF₄) or sulfur hexafluoride (SF₆), may be plasmatized and supplied as the plasmatized etching gas 36 to the workpiece 11. The etching gas may include components selected depending on the materials of the workpiece 11 and the protective film 21.

In the processing chamber 32, the plasmatized etching gas 36 supplied to the workpiece 11 acts on the workpiece 11, performing plasma etching on the workpiece 11. At this time, the plasmatized etching gas 36 flows through the linear grooves 21a in the patterned protective film 21 to the face side 11a of the workpiece 11 and acts on the exposed linear portions of the face side 11a of the workpiece 11 that overlap the streets 13, performing plasma etching on the workpiece 11 along the streets 13. As a result, the exposed linear portions of the face side 11a of the workpiece 11 that overlap the streets 13 are progressively removed from the face side 11a toward the reverse side 11b, forming linear grooves 11c in the workpiece 11 along the streets 13.

The workpiece 11 is plasma-etched continuously until the linear grooves 11c reach the reverse side 11b of the workpiece 11. When the workpiece 11 has been fully plasma-etched, the linear grooves 11c that extend from the face side 11a to the reverse side 11b are formed along the streets 13 in the workpiece 11. The linear grooves 11c thus formed divide the workpiece 11 into a plurality of chips or device chips 23 that include the respective devices 15.

As described above, the protective film 21 formed from the protective film agent 12 according to the present embodiment is prevented from cracking. Therefore, when the etching gas 36 is supplied to the workpiece 11 through the protective film 21 as a mask, the etching gas 36 is not introduced into cracks that would otherwise be present in the protective film 21 and is prevented from performing plasma etching on unwanted regions of the workpiece 11. Accordingly, the workpiece 11 is prevented from suffering processing failures.

It has been described above that the linear grooves 11c that extend from the face side 11a to the reverse side 11b are formed along the streets 13 in the workpiece 11 by plasma etching, thereby dividing the workpiece 11 into a plurality of chips. However, the workpiece 11 may be divided into chips by another process. For example, linear grooves having a depth that is smaller than the thickness of the workpiece 11 as measured from the face side 11a of the workpiece 11 may be formed along the streets 13 in the workpiece 11 by plasma etching. This process may also be referred to as half-cut dicing. The linear grooves thus formed are open at the face side 11a of the workpiece 11 and are closed at the reverse side 11b thereof. After the plasma etching, the reverse side 11b of the workpiece 11 is ground off by grindstones to thin down the workpiece 11 until the linear grooves are exposed, i.e., open, at the reverse side 11b of the workpiece 11. In this manner, the workpiece 11 is divided into a plurality of chips 23 when it has been ground.

After the completion of the division of the workpiece 11, the protective film 21 is removed from the workpiece 11. For example, a cleaning liquid such as pure water is supplied to the workpiece 11 to clean the workpiece 11 and remove the protective film 21. According to the present embodiment, since the protective film 21 contains the water-soluble resin, the protective film 21 can readily be removed from the workpiece 11 when the cleaning liquid is supplied to the workpiece 11.

As described above, the protective film agent 12 according to the present embodiment contains the water-soluble resin whose polydispersity is 4.0 or more. Therefore, the protective film 21 is not liable to crack when the protective film agent 12 is dried and solidified into the protective film 21. While the workpiece 11 is being processed, the crack-free protective film 21 protects the workpiece 11 against damage, and hence, the workpiece 11 is prevented from suffering processing failures.

According to another aspect of the present embodiment, the protective film agent 12 contains the organic solvent whose boiling point is 140° C. or higher and whose content percentage is adjusted to 3 wt % or higher. The organic solvent thus contained relieves abrupt shrinkage of the protective film 21 at the time at which the protective film agent 12 is dried into the protective film 21. As a result, the protective film 21 is prevented from cracking. Consequently, while the workpiece 11 is being processed, the crack-free protective film 21 protects the workpiece 11 against damage and prevents the workpiece 11 from suffering processing failures.

Structural and methodical details according to the present embodiment may be modified without departing from the scope of the present invention. Furthermore, structural and methodical details according to the present embodiment may be combined with those of other embodiments of the present invention.

### Second Embodiment

A second embodiment of the present invention will be described in detail below with reference to the accompanying drawings.

According to the first embodiment, the workpiece 11 is divided into the chips 23 by plasma etching. However, the method of processing the workpiece, i.e., the method of manufacturing chips according to the present invention, also covers another process, instead of plasma etching, of dividing the workpiece 11 into a plurality of chips. According to the second embodiment, a process of dividing the workpiece 11 with a laser beam will be described below.

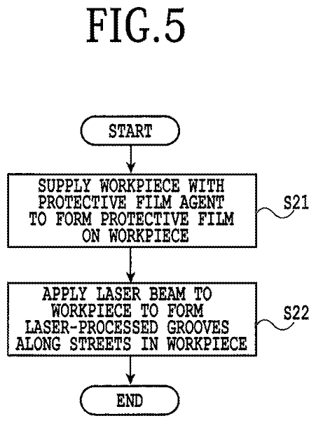

FIG. 5 is a flowchart of a method of processing a workpiece according to a modification based on the second embodiment. According to the present embodiment, the workpiece 11 is supplied with a protective film agent to coat itself with a protective film in protective film forming step S21. Thereafter, a laser beam is applied to the workpiece 11 to form laser-processed grooves along the streets 13 in the workpiece 11 in laser beam applying step S22.

Details of protective film forming step S21 are the same as those of protective film forming step S11 (see FIG. 2). In other words, protective film forming step S21 represents the method of forming the protective film 21 from the protective film agent 12 (see FIG. 3). According to the present embodiment, a method of dividing the workpiece 11 along the streets 13 into a plurality of chips will be described below as an example of the method of processing the workpiece. Protective film forming step S21 and laser beam applying step S22 altogether represent a method of manufacturing chips according to the present embodiment. The first embodiment will hereinafter be incorporated by reference wherever necessary to include appropriate passages thereof to make up for corresponding omissions in the second embodiment.

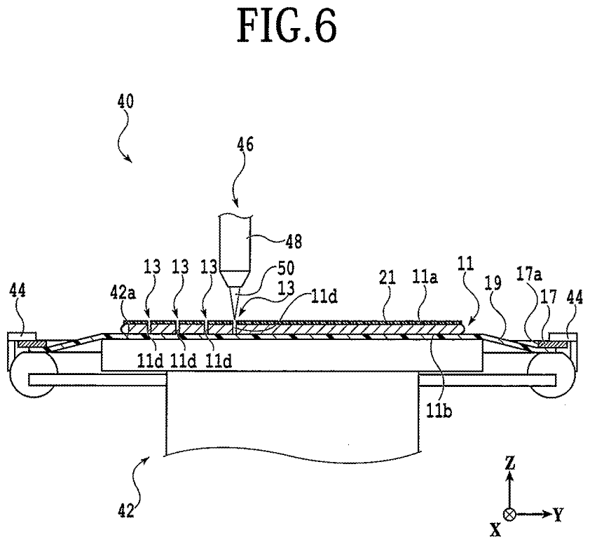

FIG. 6 illustrates in front elevation, partly in cross section, the workpiece 11 in laser beam applying step S22. The workpiece 11 is divided by way of laser processing on a laser processing apparatus 40. The protective film forming apparatus 2 (see FIG. 3) described above may be incorporated in the laser processing apparatus 40. With the protective film forming apparatus 2 incorporated in the laser processing apparatus 40, the protective film 21 can be formed on the workpiece 11 and the workpiece 11 can be laser-processed successively on the laser processing apparatus 40. The workpiece 11 may be held on a common holding table or different holding tables when the protective film 21 is formed and the workpiece 11 is laser-processed.

The laser processing apparatus 40 includes a holding table or chuck table 42 for holding the workpiece 11 thereon. The holding table 42 has a flat upper surface lying generally parallel to the horizontal plane or XY plane. The upper surface of the holding table 42 acts as a holding surface 42a for holding the workpiece 11 thereon. The holding surface 42a that is porous in nature is fluidly connected to a suction source, not depicted, such as an ejector through a fluid channel, not depicted, defined in the holding table 42 and a valve, not depicted.

The holding table 42 is coupled to a moving unit, not depicted, and a rotary actuator, not depicted. The moving unit includes a ball-screw-type moving mechanism, for example, and moves the holding table 42 in horizontal directions along the X-axis and the Y-axis. The rotary actuator includes an electric motor, for example, and rotates the holding table 42 about its central axis generally parallel to the Z-axis. A plurality of clamps 44 are provided at regular angular intervals around the holding table 42 for gripping the frame 17 that supports the workpiece 11 and securing the frame 17 in position.

The laser processing apparatus 40 includes a laser beam applying unit 46 for applying a laser beam. The laser beam applying unit 46 includes a laser oscillator, not depicted, such as a YAG laser, a YVO₄ laser, or a YLF laser, and a laser processing head 48 disposed above the holding table 42. The laser processing head 48 houses therein an optical system for guiding a pulse-oscillated laser beam 50 emitted from the laser oscillator toward the workpiece 11. The optical system has optical elements including among others a condensing lens for focusing the laser beam 50 at a predetermined position. The laser beam 50 applied from the laser processing head 48 to the workpiece 11 processes the workpiece 11.

In preparation for the laser processing of the workpiece 11, the workpiece 11 is placed and held on the holding table 42. Specifically, the workpiece 11 is placed on the holding surface 42a of the holding table 42 such that the face side 11a, i.e., the protective film 21 side, faces upwardly and the reverse side 11b, i.e., the sheet 19 side, faces the holding surface 42a. The frame 17 is secured in position by the clamps 44. Then, the suction source is actuated to apply a suction force, i.e., a negative pressure, to the holding surface 42a, causing the holding table 42 to hold the workpiece 11 under suction on the holding surface 42a with the sheet 19 interposed therebetween.

The holding table 42 is rotated about its central axis to orient the longitudinal direction of one of the streets 13 to be parallel to the X-axis that represents a processing-feed direction. Moreover, the holding table 42 is moved to adjust its position along the Y-axis that represents an indexing-feed direction until a region to be irradiated with the laser beam 50 is positioned on an extension of the street 13. Furthermore, the position of the laser processing head 48 and the layout of the optical system are adjusted to position the focused spot of the laser beam 50 at the same height as the workpiece 11.

Now, while the laser processing head 48 is emitting the laser beam 50, the holding table 42 is moved along the X-axis with respect to laser processing head 48. Accordingly, the holding table 42 and the laser beam 50 are moved relative to each other along the X-axis at a predetermined speed, i.e., a predetermined processing-feed rate, during which time the laser beam 50 is applied to the workpiece 11 through the protective film 21. As a result, the workpiece 11 is processed along the street 13 by the laser beam 50.

Conditions in which the laser beam 50 is applied to the workpiece 11 are established so as to process the workpiece 11 by way of laser ablation. Specifically, the laser beam 50 has a wavelength selected to cause at least part thereof to be absorbed by the workpiece 11. In other words, the laser beam 50 is a laser beam absorbable by the workpiece 11. Other conditions in which the laser beam 50 is applied to the workpiece 11 are also established so as to ablate the workpiece 11 appropriately. For example, if the workpiece 11 is a monocrystalline silicon wafer, then conditions in which the laser beam 50 is applied to the workpiece 11 may be established as follows:
Wavelength: 355 to 532 nm
Average output power: 1 to 100 W
Repetitive frequency: 100 to 10,000 kHz
Processing-feed rate: 200 to 1,000 mm/s

When the laser beam 50 is applied to the workpiece 11 along the street 13, an elongate linear portion of the workpiece 11 that is irradiated with the laser beam 50 along the street 13 is removed by way of laser ablation, leaving a laser-processed linear groove 11d that extend from the face side 11a to the reverse side 11b along the street 13 in the workpiece 11. As a result, the workpiece 11 is divided along the street 13. At this time, the laser beam 50 may be applied through the protective film 21 to the workpiece 11 or may be applied to the protective film 21 and the workpiece 11 to remove irradiated elongate linear portions from both of them.

When the workpiece 11 is thus laser-processed, the workpiece 11 produces swarf such as debris from its elongate linear portions irradiated with the laser beam 50. However, inasmuch as the protective film 21 is present on the face side 11a of the workpiece 11, the protective film 21 blocks the swarf from being deposited on the face side 11a of the workpiece 11. Consequently, the workpiece 11 is prevented from being contaminated by the swarf.

As described above, the protective film 21 formed from the protective film agent 12 according to the present embodiment is prevented from cracking. Therefore, when the workpiece 11 is processed by the laser beam 50, the workpiece 11 is prevented from being protected insufficiently due to cracks that would otherwise be present in the protective film 21, i.e., is protected sufficiently by the crack-free protective film 21. The protective film 21 is effective to prevent swarf from being deposited on the workpiece 11, so that the workpiece 11 is prevented from suffering processing failures.

Thereafter, the laser processing of the workpiece 11 described above is repeated along the other streets 13 to form laser-processed linear grooves 11d. When the laser-processed linear grooves 11d are formed along all the streets 13 in the workpiece 11, the workpiece 11 is divided into a plurality of chips 23 (see FIG. 4B) that include the respective devices 15.

For dividing the workpiece 11 by way of laser ablation, the laser beam 50 may be applied to the workpiece 11 repeatedly in a plurality of strokes along each of the streets 13 to form a laser-processed linear groove 11d in the workpiece 11. In this case, it is possible to form a laser-processed linear groove 11d extending from the face side 11a to the reverse side 11b of the workpiece 11 with a reduced average output power level of the laser beam 50. The reduced average output power level of the laser beam 50 minimizes its adverse thermal effects on the workpiece 11 and the devices 15, thereby making the workpiece 11 less likely to suffer processing failures.

It has been described above that the laser-processed linear grooves 11d that extend from the face side 11a to the reverse side 11b are formed along the streets 13 in the workpiece 11 by applying the laser beam 50, thereby dividing the workpiece 11 into a plurality of chips. However, the workpiece 11 may be divided into chips by another process. For example, laser-processed linear grooves having a depth that is smaller than the thickness of the workpiece 11 as measured from the face side 11a of the workpiece 11 may be formed along the streets 13 in the workpiece 11 by applying the laser beam 50. This process may also be referred to as half-cut dicing. The laser-processed linear grooves thus formed are open at the face side 11a of the workpiece 11 and are closed at the reverse side 11b thereof. After the laser processing, the reverse side 11b of the workpiece 11 is ground off by grindstones to thin down the workpiece 11 until the laser-processed linear grooves are exposed, i.e., open, at the reverse side 11b of the workpiece 11. In this manner, the workpiece 11 is divided into a plurality of chips 23 when it has been ground.

Alternatively, after the workpiece 11 has been processed by half-cut dicing, an external force may be applied to the workpiece 11 to rupture the workpiece 11 at the laser-processed linear grooves, thereby dividing the workpiece 11 along the streets 13. Further alternatively, after the workpiece 11 has been processed by half-cut dicing, an annular cutting blade that is rotating about its central axis may be caused to cut into the bottoms of the laser-processed linear grooves to divide the workpiece 11 along the streets 13.

After the completion of the division of the workpiece 11, the protective film 21 is removed from the workpiece 11. For example, a cleaning liquid such as pure water is supplied to the workpiece 11 to clean the workpiece 11 and remove the protective film 21.

As described above, the protective film 21 formed from the protective film agent 12 according to the present embodiment is prevented from cracking. Therefore, when the workpiece 11 is laser-processed, the workpiece 11 is protected appropriately by the crack-free protective film 21. Thus, the workpiece 11 is prevented from suffering processing failures.

Structural and methodical details according to the present embodiment may be modified without departing from the scope of the present invention. Furthermore, structural and methodical details according to the present embodiment may be combined with those of other embodiments of the present invention.

### First Exemplary Embodiment

The results of an assessment of protective films formed from the protective film agent according to the aspect of the present invention will be described below. The assessment involves an observation and comparison of a protective film according to Comparative Example that was formed from a protective film agent containing a water-soluble resin having a polydispersity less than 4.0 and protective films according to Inventive Examples 1 and 2 that were formed from protective film agents containing water-soluble resins each having a polydispersity of 4.0 or more.

Each of the protective film agents according to Comparative Example and Inventive Examples 1 and 2 contained 74.9 wt % of water, 13.3 wt % of a water-soluble resin, 10.8 wt % of a solvent, i.e., PGME, and 1.0 wt % of a light absorber, i.e., α-glucosylrutin. The water-soluble resin of the protective film agent according to Comparative Example was a PVP having a K value of 50. The water-soluble resin of the protective film agent according to Inventive Example 1 was a resin obtained by mixing a PVP having a K value of 50 (low-molecular-weight product) and a PVP having a K value of 90 (high-molecular-weight product) with each other at a ratio of 9:1. The water-soluble resin of the protective film agent according to Inventive Example 2 was similar to the water-soluble resin according to Inventive Example 1 except that the PVP having the K value of 50 and the PVP having the K value of 90 were mixed with each other at a ratio of 7:3.

The water-soluble resins of the protective film agents according to Comparative Example and Inventive Examples 1 and 2 had number average molecular weights Mn, weight average molecular weights Mw, and polydispersities Mw/Mn as indicated by Table 1 below. The number average molecular weights and the weight average molecular weights were measured and analyzed using a gel permeation chromatography (reference material: polyethylene glycol resin, mobile phase: 1-methyl-2-pyrrolidone, analyzing software: LabSolutions manufactured by Shimadzu Corporation).

TABLE 1

| | Number | Weight | | |
|---|---|---|---|---|
| | average | average | | |
| | molecular | molecular | | |
| | weight | weight | Polydispersity | |
| | (Mn) | (Mw) | (Mw/Mn) | Evaluation |
| Comparative | 5.6 × 10⁴ | 1.2 × 10⁵ | 2.2 | Poor |
| example | | | | |
| Inventive | 4.9 × 10⁴ | 2.0 × 10⁵ | 4.2 | Good |
| example 1 | | | | |
| Inventive | 3.7 × 10⁴ | 4.1 × 10⁵ | 11.1 | Good |
| example 2 | | | | |

Protective films were formed on the surfaces of workpieces from the protective film agents according to Comparative Example and Inventive Examples 1 and 2. Each of the workpieces was a silicon wafer having a plurality of bumps, i.e., spherical connection electrodes, on its surface. The protective films were formed on the surfaces of the silicon wafers from the protective film agents according to Comparative Example and Inventive Examples 1 and 2, thereby coating the entire surfaces including the bumps of the silicon wafers with the protective films.

Then, three observation areas where bumps are present in a field of view were selected at random from each of the protective films according to Comparative Example and Inventive Examples 1 and 2 and observed using a scanning electron microscope. Those protective films in which no crack was found in the observation areas were assessed as “good” whereas those protective films in which at least one crack was found in the observation areas were assessed as “poor.”

On the protective film according to Comparative Example, a number of cracks were confirmed in the observation areas. It is assumed for this observation that the cracks were formed by the shrinkage of the water-soluble resin at the time at which the protective film agent was dried. On the protective films according to Inventive Examples 1 and 2, however, no crack was confirmed in the observation areas. It is assumed for the latter observation that since the water-soluble resins with the high polydispersities were used, the protective films had tenacity derived from the high-molecular-weight components and flexibility derived from the low-molecular-weight component and were unlikely to crack due to shrinkage. It was thus confirmed that the protective films that were less liable to crack and high in quality were formed by using the protective film agents according to the aspect of the present invention.

### Second Exemplary Embodiment

The results of an assessment of protective films formed from the protective film agent according to the other aspect of the present invention will be described below. The assessment involves an observation and comparison of a protective film according to Comparative Example that was formed from a protective film agent containing an organic solvent having a boiling point lower than 140° C. and protective films according to Inventive Examples 1 through 8 that were formed from protective film agents containing organic solvents having boiling points of 140° C. or higher.

Each of the protective film agents according to Comparative Example and Inventive Examples 1 and 3 through 7 contained 69.5 wt % of water, 19 wt % of a water-soluble resin, i.e., a PVP having a K value of 50, 10 wt % of an organic solvent, and 1.5 wt % of a light absorber, i.e., α-glucosylrutin. The components of the protective film agent according to Inventive Example 2 were similar to those of the protective film agent according to Inventive Example 1 except that they included 19.5 wt % of water and 50 wt % of an organic solvent. The protective film agent according to Inventive Example 8 contained 43.0 wt % of water, 6.0 wt % of a water-soluble resin, i.e., a PVP having a K value of 50, 50.0 wt % of an organic solvent, and 1.0 wt % of a light absorber, i.e., α-glucosylrutin. The protective film agents according to Comparative Example and Inventive Examples 1 through 8 contained organic solvents, their boiling points, and their content percentages as indicated by Table 2 below. As illustrated in Table 2, the protective film agents according to Inventive Examples 1 through 8 contained 10 wt % or more of organic solvents having boiling points of 150° C. or higher.

TABLE 2

| | | Boiling | Content | | |
|---|---|---|---|---|---|
| | Organic | point | percentage | Forming | |
| | solvent | [° C.] | [wt %] | process | Evaluation |
| Compar- | Propylene | 120 | 10 | Spin | Poor |
| ative | glycol | | | coating | |
| example | methyl | | | | |
| | ether | | | | |
| Inventive | Propylene | 150 | 10 | Spin | Good |
| example 1 | glycol | | | coating | |
| | propyl | | | | |
| | ether | | | | |
| Inventive | Propylene | 150 | 50 | Spin | Good |
| example 2 | glycol | | | coating | |
| | propyl | | | | |
| | ether | | | | |
| Inventive | 3-methoxy-3- | 174 | 10 | Spin | Good |
| example 3 | methyl-1- | | | coating | |
| | butanol | | | | |
| Inventive | Propylene | 187 | 10 | Spin | Good |
| example 4 | glycol | | | coating | |
| Inventive | Dipropylene | 190 | 10 | Spin | Good |
| example 5 | glycol methyl | | | coating | |
| | ether | | | | |
| Inventive | 1-methyl-2- | 202 | 10 | Spin | Good |
| example 6 | pyrrolidone | | | coating | |
| Inventive | Polyethylene | 250 | 10 | Spin | Good |
| example 7 | glycol 200 | | | coating | |
| Inventive | Dipropylene | 190 | 50 | Spray | Good |
| example 8 | glycol methyl | | | coating | |
| | ether | | | | |

Protective films were formed on the surfaces of workpieces from the protective film agents according to Comparative Example and Inventive Examples 1 through 8. Each of the workpieces was a silicon wafer having a plurality of bumps, i.e., spherical connection electrodes, on its surface. The protective films were formed on the surfaces of the silicon wafers from the protective film agents according to Comparative Example and Inventive Examples 1 through 8, thereby coating the entire surfaces including the bumps of the silicon wafers with the protective films.

Each of the protective films according to Inventive Examples 1 through 7 was formed by way of spin coating. Specifically, the silicon wafer was held on a spinner table and supplied with the protective film agent. Then, the spinner table was rotated at a rotational speed of 400 rpm for a period of 1 minute, then at a rotational speed of 800 rpm for a period of 1 minute, and thereafter at a rotational speed of 2,000 rpm for a period of 3 minutes, thereby drying the protective film agent on the silicon wafer.

The protective film according to Inventive Example 8 was formed by spray coating. Specifically, a two-fluid nozzle was used to atomize the protective film agent, and the atomized protective film agent was discharged at a rate of 1 mL/min. based on adjustment and supplied to the silicon wafer, thereby coating the silicon wafer with the protective film agent. Thereafter, the protective film agent was dried into the protective film.

Then, three observation areas where bumps are present in a field of view were selected at random from each of the protective films according to Comparative Example and Inventive Examples 1 through 8 and observed using a scanning electron microscope. Those protective films in which no crack was found in the observation areas were assessed as “good” whereas those protective films in which at least one crack was found in the observation areas were assessed as “poor.”

On the protective film according to Comparative Example, a number of cracks were confirmed in the observation areas. It is assumed for this observation that the cracks were formed by the shrinkage of the water-soluble resin at the time at which the protective film agent was dried. On the protective films according to Inventive Examples 1 and 2, however, no crack was confirmed in the observation areas. It is assumed for the latter observation that since the protective film agent contained at least a certain amount of high-boiling-point organic solvent, abrupt shrinkage of the protective film at the time at which the protective film agent was dried was relieved, the protective film is less liable to crack. It was thus confirmed that the protective films that were less liable to crack and high in quality were formed by using the protective film agents according to the other aspect of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A protective film agent from which to form a protective film on a workpiece, the protective film agent comprising:
a water-soluble resin whose polydispersity is 4.0 or more.

2. The protective film agent according to claim 1, wherein the water-soluble resin has a number average molecular weight in a range from 10,000 to 50,000 and a weight average molecular weight in a range from 200,000 to 1,500,000.

3. The protective film agent according to claim 1, further comprising:
a light absorber.

4. The protective film agent according to claim 1, further comprising:
water as a solvent.

5. The protective film agent according to claim 4, further comprising:
an organic solvent as the solvent.

6. A method of processing a workpiece along streets established thereon, the method comprising:
supplying the workpiece with a protective film agent that includes a water-soluble resin whose polydispersity is 4.0 or more to form a protective film on the workpiece;
applying a laser beam that is absorbable by the protective film to a portion of the protective film along the streets to remove the portion of the protective film along the streets; and
supplying the workpiece with a plasmatized etching gas through the protective film to perform plasma etching on the workpiece along the streets.

7. A method of processing a workpiece along streets established thereon, the method comprising:
supplying the workpiece with a protective film agent that includes a water-soluble resin whose polydispersity is 4.0 or more to form a protective film on the workpiece; and
applying a laser beam that is absorbable by the workpiece through the protective film to the workpiece along the streets to form laser-processed grooves along the streets in the workpiece.

8. A protective film agent from which to form a protective film on a workpiece, the protective film agent comprising:
a water-soluble resin; and
an organic solvent,
wherein the organic solvent has a boiling point of 140° C. or higher, and
the organic solvent has a content percentage of 3 wt % or higher.

9. The protective film agent according to claim 8, further comprising:
a light absorber.

10. The protective film agent according to claim 8, further comprising:
water.

11. The protective film agent according to claim 10, wherein the organic solvent is a water-soluble organic solvent.

12. A method of processing a workpiece along streets established thereon, the method comprising:
supplying the workpiece with a protective film agent including a water-soluble resin and an organic solvent, the organic solvent having a boiling point of 140° C. or higher and having a content percentage of 3 wt % or higher, to form a protective film on the workpiece;
applying a laser beam that is absorbable by the protective film to a portion of the protective film along the streets to remove the portion of the protective film along the streets; and
supplying the workpiece with a plasmatized etching gas through the protective film to perform plasma etching on the workpiece along the streets.

13. A method of processing a workpiece along streets established thereon, the method comprising:
supplying the workpiece with a protective film agent including a water-soluble resin and an organic solvent, the organic solvent having a boiling point of 140° C. or higher and having a content percentage of 3 wt % or higher, to form a protective film on the workpiece; and
applying a laser beam that is absorbable by the workpiece through the protective film to the workpiece along the streets to form laser-processed grooves along the streets in the workpiece.
